(19) United States
(12) Patent Application Publication
(10) Pub. No.: US 2023/0015082 A1
(43) Pub. Date: Jan. 19, 2023

(54) MEASUREMENT MARK, SEMICONDUCTOR STRUCTURE, MEASUREMENT METHOD AND DEVICE, AND STORAGE MEDIUM

(71) Applicant: CHANGXIN MEMORY TECHNOLOGIES, INC., Hefei City (CN)

(72) Inventor: Shaowen QIU, Hefei City (CN)

(21) Appl. No.: 17/500,304

(22) Filed: Oct. 13, 2021

Related U.S. Application Data
(63) Continuation of application No. PCT/CN2021/107657, filed on Jul. 21, 2021.

(30) Foreign Application Priority Data
Jul. 15, 2021 (CN) 202110799563.1

(51) Int. Cl. H01L 21/66; H01L 23/544

(52) U.S. Cl. CPC H01L 22/12; H01L 23/544; H01L 2223/54426

(57) ABSTRACT

The present disclosure relates to a measurement mark, a semiconductor structure, a measurement method and device, and a storage medium. The measurement mark is provided on a semiconductor structure, the semiconductor structure including a substrate. The measurement mark is applied to an after etching inspection process. The measurement mark includes a first mark layer and a second mark layer, the first mark layer and the second mark layer being stacked. A projection contour of the first mark layer on the substrate coincides with a projection contour of the second mark layer on the substrate. The measurement mark includes a first mark group located on the first mark layer and a second mark group located on the second mark layer.

### CROSS-REFERENCE TO RELATED APPLICATIONS

This is a continuation of International Application No. PCT/CN2021/107657, filed on Jul. 21, 2021, which claims the priority to Chinese Patent Application 202110799563.1, titled “MEASUREMENT MARK, SEMICONDUCTOR STRUCTURE, MEASUREMENT METHOD AND DEVICE, AND STORAGE MEDIUM”, filed with China National Intellectual Property Administration (CNIPA) on Jul. 15, 2021. The entire contents of International Application No. PCT/CN2021/107657 and Chinese Patent Application 202110799563.1 are incorporated herein by reference.

### TECHNICAL FIELD

Embodiments of the present disclosure relate to, but are not limited to, a measurement mark, a semiconductor structure, a measurement method and device, and a storage medium.

### BACKGROUND

A semiconductor structure typically includes multiple patterned material layers. Each current layer must be aligned with a previous layer within a strict tolerance. The alignment error between the current layer and the previous layer of the semiconductor structure is called an overlay error. The overlay error depicts a deviation of the pattern of the current layer relative to the pattern of the previous layer in X and Y directions (refer to FIG. 1) of the wafer surface and the distribution of the deviation on the wafer surface. The overlay error is a key indicator to determine the quality of the photolithography process.

### SUMMARY

An overview of the subject matter detailed in the present disclosure is provided below, which is not intended to limit the protection scope of the claims.

The present disclosure provides a measurement mark, a semiconductor structure, a measurement method, a device and a storage medium.

A first aspect of embodiments of the present disclosure provides a measurement mark for an overlay error. The measurement mark is provided on a semiconductor structure, the semiconductor structure including a substrate; the measurement mark is applied to an after etching inspection (AEI) process; the measurement mark includes a first mark layer and a second mark layer, the first mark layer and the second mark layer being stacked; a projection contour of the first mark layer on the substrate coincides with a projection contour of the second mark layer on the substrate;

the measurement mark includes a first mark group located on the first mark layer and a second mark group located on the second mark layer; and

the measurement mark is configured such that after measurement light passes through the first mark group and the second mark group, an intensity distribution of zero-order diffracted light of the measurement light is asymmetric.

A second aspect of the embodiments of the present disclosure provides a semiconductor structure. The semiconductor structure is provided with the measurement mark as described in the first aspect.

A third aspect of the embodiments of the present disclosure provides a measurement method for an overlay error. The measurement method includes:

controlling measurement light to be incident from a first mark layer of a semiconductor structure after the semiconductor structure is etched, and collecting zero-order diffracted light after the measurement light passes through a first mark group of the first mark layer and a second mark group of a second mark layer of the semiconductor structure, wherein the first mark layer and the second mark layer form the measurement mark as described in the first aspect, and the measurement mark is located in a scribe lane region of the semiconductor structure; and

determining an overlay error between a first layer and a second layer based on an intensity distribution of the zero-order diffracted light.

A fourth aspect of the embodiments of the present disclosure provides a measurement device for an overlay error. The measurement device includes:

a processor; and

a memory for storing an instruction executable by the processor;

the processor being configured to execute the measurement method as described in the third aspect.

A fifth aspect of the embodiments of the present disclosure provides a non-transitory computer-readable storage medium. When an instruction in the storage medium is executed by a processor of a measurement device, the measurement device executes the measurement method as described in the third aspect.

It should be understood that the above general description and the following detailed description are only exemplary and explanatory, and should not be construed as a limitation to the present disclosure.

### BRIEF DESCRIPTION OF THE DRAWINGS

The drawings incorporated into the specification and constituting part of the specification illustrate the embodiments of the present disclosure, and are used together with the description to explain the principles of the embodiments of the present disclosure.

In these drawings, similar reference numerals are used to represent similar elements. The drawings in the following description are part rather than all of the embodiments of the present disclosure. Persons of ordinary skill in the art may obtain other drawings according to these drawings without creative efforts.

FIG. 1a is a schematic view of image-based overlay (1130) technology and scanning electron microscope (SEM) measurement.

FIG. 1 is a schematic view of a measurement mark according to an exemplary embodiment.

FIG. 2 is a schematic view of a first layer and a second layer of a semiconductor structure according to an example.

FIG. 3 is a schematic view of a semiconductor structure according to an example.

FIG. 4 is a top view of a measurement mark according to an example.

FIG. 5 is a top view of a measurement mark according to an example.

FIG. 6 is a top view of a measurement mark according to an example.

FIG. 7 is a top view of a measurement mark according to an example.

FIG. 8 is a top view of a measurement mark according to an example.

FIG. 9 is a top view of a measurement mark according to an example.

FIG. 10 is a top view of a measurement mark according to an example.

FIG. 11 is a top view of a measurement mark according to an example.

FIG. 12 is a top view of a measurement mark according to an example.

FIG. 13 is a top view of a measurement mark according to an example.

FIG. 14 is a top view of a measurement mark according to an example.

FIG. 15 is a top view of a measurement mark according to an example.

FIG. 16 is a top view of a measurement mark according to an example.

FIG. 17 is a flowchart of a measurement method according to an example.

FIG. 18 is a block diagram of a measurement device according to an example.

Reference Numerals: 1. semiconductor structure; 10. first layer; 20. second layer; 30. substrate; 11. active area; 12. scribe lane region; 2. measurement mark; 100. first mark layer; 110. first mark group; 111. first mark unit; 200. second mark layer; 210. second mark group; 211. second mark unit; 300. measurement pair; 310. sub-pair; 3. measurement device; 31. processor; and 32. memory.

### DETAILED DESCRIPTION

In order to make the objectives, technical solutions and advantages of the embodiments of the present disclosure more clear, the technical solutions in the embodiments of the present disclosure will be clearly and completely described below in conjunction with the drawings in the embodiments of the present disclosure. Apparently, the described embodiments are some rather than all of the embodiments of the present disclosure. All other embodiments derived by persons of ordinary skill in the art on the basis of the embodiments in the present disclosure without creative efforts should fall within the protection scope of the present disclosure. It should be noted that the embodiments in the present disclosure and the features in the embodiments may be combined with each other in a non-conflicting manner.

Overlay error inspection is generally divided into after development inspection (ADI) and after etching inspection (AEI).

ADI refers to critical dimension (CD) measurement after development. ADI is generally used to test the performance indicators of exposure machine and developing machine. After the exposure and development are completed, a generated pattern is qualitatively inspected through an ADI machine to check whether the pattern is normal. Since the pattern cannot be measured by transmitted light, ADI generally measures the pattern by electron beam, scanning electron microscope (SEM) or other means.

AEI refers to CD measurement after etching. In the etching process, a full inspection or sampling inspection is performed on the product before and after the photoresist is removed.

The overlay error can generally be measured by image-based overlay (IBO) technology, SEM, and in-device metrology (IDM, or in-die measurement) technology.

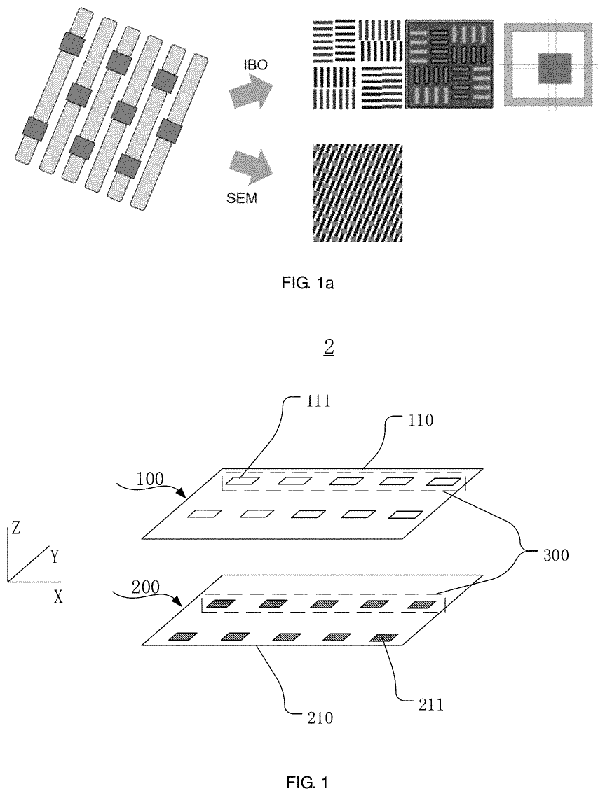

SEM (refer to FIG. 1 a) is generally used for ADI. However, it cannot accurately measure the overlay error of an opening layer with an opening in the semiconductor structure in horizontal and longitudinal directions (refer to the X and Y directions shown in FIG. 1). IBO (refer to FIG. 1 a) is generally also used for ADI, and it relies on a measurement mark for measurement. IBO also cannot accurately measure the overlay error of an opening layer with an opening in the semiconductor structure. IDM is generally used for AEI. It does not need to set a specific measurement mark, but uses the original pattern of the semiconductor structure to measure the overlay error. However, IDM relies on the asymmetry of the intensity distribution of the zero-order diffracted light for measurement. For the opening layer with an opening in the semiconductor structure, there is no asymmetry in the intensity distribution of the zero-order diffracted light after it passes through the original patterns of a current layer and a previous layer. Therefore, in this case, IDM cannot measure the overlay error.

The present disclosure provides a measurement mark for an overlay error, which is applied to AEI. After measurement light passes through the measurement mark, an intensity distribution of zero-order diffracted light of the measurement light is asymmetric. According to the asymmetry of the intensity distribution of the zero-order diffracted light, an overlay error between a first mark group of a first mark layer (for example, a current layer) and a second mark group of a second mark layer (for example, a previous layer) in the measurement mark can be calculated. In this way, the overlay error between the current layer and the previous layer of the semiconductor structure can be obtained, thereby realizing accurate measurement of the overlay error. The measurement mark can be used to measure the overlay error between any two layers of the semiconductor structure.

An exemplary embodiment provides a measurement mark for an overlay error. The measurement mark is provided on a semiconductor structure to realize AEI between two layers of the semiconductor structure, so as to complete the measurement of the overlay error.

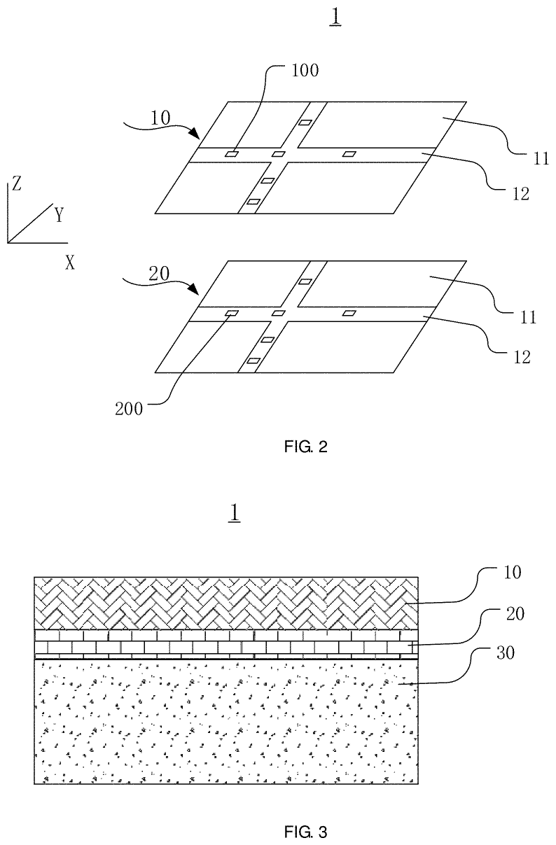

Referring to FIGS. 1 to 3, a measurement mark 2 may include a first mark layer 100 and a second mark layer 200, and the first mark layer 100 and the second mark layer 200 are stacked, that is, the first mark layer 100 and the second mark layer 200 are arranged in a vertical direction (refer to the Z direction shown in FIG. 1). The first mark layer 100 is a first layer 10 of two layers involved in the overlay error inspection, and the second mark layer 200 is a second layer 20 of the two layers involved in the overlay error inspection. The first layer 10 may be a current layer, and the second layer 20 may be a previous layer.

A semiconductor structure 1 includes a substrate 30. The first mark layer 100 and the second mark layer 200 are respectively located above the substrate 30. A projection contour of the first mark layer 100 on the substrate 30 coincides with that of the second mark layer 200 on the substrate 30. The measurement mark 2 includes a first mark group 110 located on the first mark layer 100 and a second mark group 210 located on the second mark layer 200. That is, the first mark group 110 and the second mark group 210 form a pair of mark groups to form the zero-order diffracted light of the measurement light.

The measurement mark 2 is configured such that after measurement light passes through the first mark group 110 and the second mark group 210, an intensity distribution of the zero-order diffracted light of the measurement light is asymmetric.

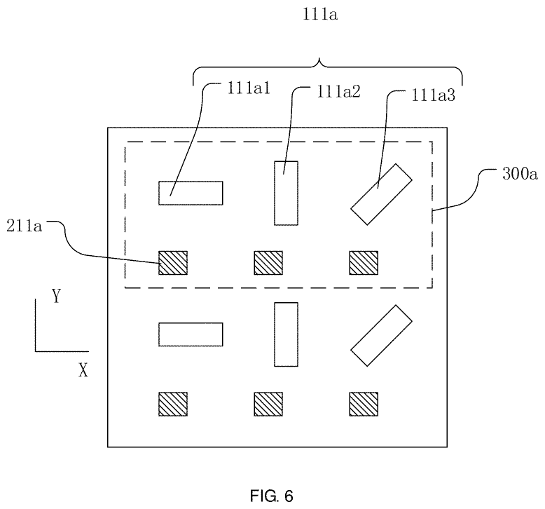

Referring to FIGS. 1 and 6, the measurement mark 2 may include at least one measurement pair 300. When there is more than one measurement pair, multiple (two or more) measurement pairs 300 may be the same or different.

Referring to FIG. 1, each measurement pair 300 may include multiple first mark units 111 in the first mark group 110 (refer to multiple first mark units 111 in the dotted frame in the first mark group 110 in FIG. 1) and multiple second mark units 211 in the second mark group 210 (refer to multiple second mark units 211 in the dotted frame in the second mark group 210 in FIG. 1). Projections of multiple measurement pairs on the substrate 30 are staggered.

The first mark units 111 may be openings or physical marks (for example, patches, films, etc.). The second mark units 211 may also be openings or physical marks. After the measurement light passes through the first mark group 110 and the second mark group 210, the intensity distribution of the zero-order diffracted light is asymmetric.

In each measurement pair 300, the multiple first mark units 111 are arranged in a first preset manner, and the multiple second mark units 211 are also arranged in the first preset manner. That is, the multiple first mark units 111 are arranged in the same manner as the multiple second mark units 211. The first preset manner may be a row manner or a column manner, and may also be other manner besides the column manner or the row manner. The row manner refers to a horizontal arrangement manner (refer to the X direction in FIG. 1), and the column manner refers to a longitudinal arrangement manner (refer to the Y direction in FIG. 1). The horizontal, longitudinal and vertical directions are perpendicular to each other.

For example, referring to FIG. 6, the first preset manner is a row manner. The dotted lines in FIG. 6 are only to show a first mark unit 111a and a second mark unit 211a included in a measurement pair 300a. In the measurement pair 300a, multiple first mark units 111a are arranged in a row manner, and multiple second mark units 211a are also arranged in a row manner.

For example, referring to FIG. 14, the first preset manner is a column manner. The dotted lines in FIG. 14 are only to show a first mark unit 111i and a second mark unit 211i included in a measurement pair 300i. In the measurement pair 300i, multiple first mark units 111i are arranged in a column manner, and multiple second mark units 211i are also arranged in a column manner.

It should be noted that, in the measurement mark, the first mark units located on the first mark layer and the second mark units located on the second mark layer may not be in pairs.

For example, the first mark layer may include multiple rows of first mark units, and each row of first mark units may include multiple first mark units. The second mark layer may include multiple rows of second mark units, and each row of second mark units may include multiple second mark units. The row number of the first mark units on the first mark layer is denoted as a first row number, and the row number of the second mark units on the second mark layer is denoted as a second row number. The first row number and the second row number may be different or the same.

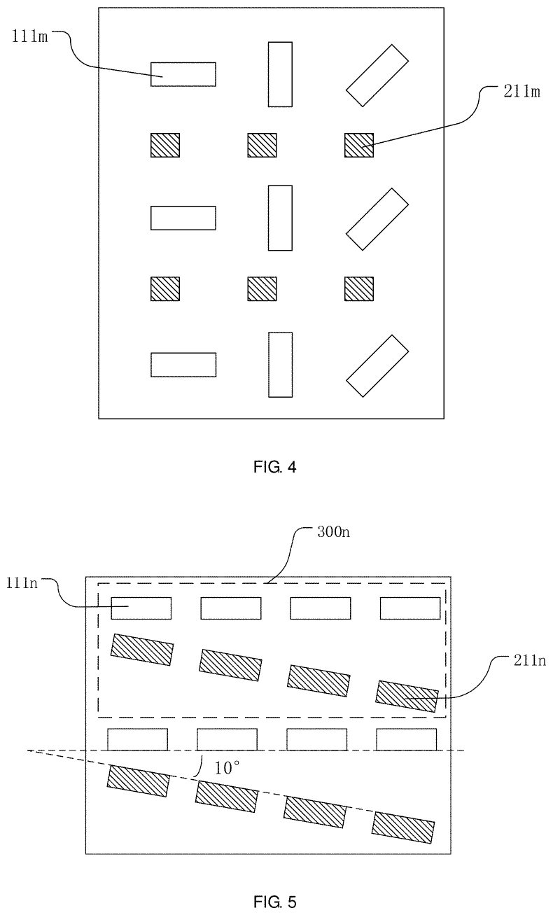

Referring to FIG. 4, when the first row number is different from the second row number, the first mark units located on the first mark layer and the second mark units located on the second mark layer are not in pairs, or there is at least one unpaired row of first mark units or second mark units.

Referring to FIG. 6, when the first row number is the same as the second row number, the measurement mark may include the same number of measurement pairs as the first row number.

It should also be noted that, in the measurement pair, the arrangement manner of the multiple first mark units and the arrangement manner of the multiple second mark units may also be different. When the arrangement manners of the first and second mark units in the measurement pair are different, the arrangement manner of the multiple first mark units may be the same, and the arrangement manner of the multiple second mark units may also be the same.

For example, referring to FIG. 5 (the dotted lines in the figure are only to show an angle of 10°), in a measurement pair 300n, multiple first mark units 111n are arranged in a horizontal direction (that is, arranged in a row manner), and multiple second mark units 211n are arranged in a direction at an angle of 10° to the horizontal direction. In this case, the length directions of the multiple first mark units 111n are respectively parallel to the horizontal direction, and the length directions of the multiple second mark units 211n are respectively at an angle of 10° to the horizontal direction.

When the measurement mark is used to measure an overlay error, a measurement light source illuminates the position of the measurement mark, and the measurement light emitted by the measurement light source passes through the first mark group and the second mark group to form multi-order diffracted light. The zero-order diffracted light is collected from the multi-order diffracted light, and the intensity distribution of the zero-order diffracted light is obtained. According to the asymmetry of the intensity distribution, the overlay error of the first mark layer and the second mark layer is determined. Thus, the overlay error of the first layer and the second layer of the semiconductor structure is determined, thereby realizing the measurement of the overlay error of the first layer and the second layer.

In addition, after the measurement light passes through the first mark group and the second mark group of the measurement mark, the intensity distribution of the zero-order diffracted light is asymmetric. Therefore, the overlay error between any two layers can be measured by the measurement mark, without being limited by the image of the active areas of each layer, thereby expanding the application range of the diffraction-based overlay error measurement.

The first layer may be an opening layer of the semiconductor structure, that is, the first mark layer may be located in an opening layer of the semiconductor structure, so as to complete the measurement of the overlay error between the opening layer and other layer.

It should be noted that the first layer and the second layer may be two adjacent layers (as shown in FIG. 3), or two non-adjacent layers (not shown in the figure). That is, there may be no other layer or some other layer between the first layer and the second layer. The second layer may be in direct contact with the substrate (as shown in FIG. 3), and other layer (not shown in the figure) may also be provided between the second layer and the substrate.

An exemplary embodiment provides a measurement mark. In the measurement mark, in each measurement pair, multiple first mark units may be arranged in different manners or multiple second mark units may be arranged in different manners. Alternatively, multiple first mark units may be arranged in different manners and multiple second mark units may also be arranged in different manners.

### Example 1

Referring to FIG. 6, the first mark units 111a are rectangular units, and the second mark units 211a are square units.

In each measurement pair 300a, the first preset manner is the same as the second preset manner. The multiple first mark units 111a are arranged in different manners, and the multiple second mark units 211a are arranged in the same manner.

The length direction of a part (i.e. at least one) of first mark units 111a1 is along a row direction, the length direction of a part of first mark units 111a2 is along a direction perpendicular to the row direction (i.e. a column direction), and the length direction of a part of first mark units 111a3 is at an angle of 45° to the row direction.

### Example 2

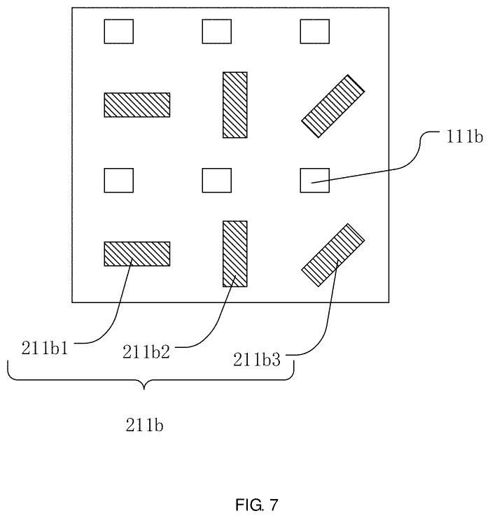

Referring to FIG. 7, first mark units 111b are square units, and second mark units 211b are rectangular units.

In each measurement pair, the first preset manner is the same as the second preset manner. The multiple first mark units 111b are arranged in the same manner, and the multiple second mark units 211b are arranged in different manners.

The length direction of a part (i.e. at least one) of second mark units 211b1 is along a row direction, the length direction of a part of second mark units 211b2 is along a direction perpendicular to the row direction (i.e. a column direction), and the length direction of a part of second mark units 211b3 is at an angle of 45° to the row direction.

### Example 3

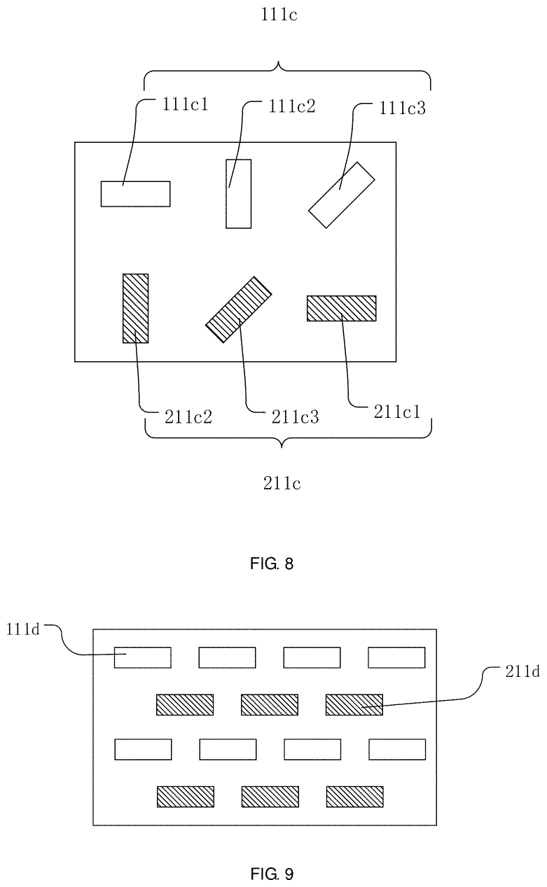

Referring to FIG. 8, first mark units 111c are first rectangular units, and second mark units 211c are second rectangular units.

In each measurement pair, the first preset manner is the same as the second preset manner. The multiple first mark units 111c are arranged in different manners, and the multiple second mark units 211c are also arranged in different manners.

The length direction of a first part of first mark units 111c1 is along a row direction, the length direction of a second part of first mark units 111c2 is along a direction perpendicular to the row direction (i.e. a column direction), and the length direction of a third part of first mark units 111c3 is at an angle of 45° to the row direction. The length direction of a first part of second mark units 211c1 is along a row direction, the length direction of a second part of second mark units 211c2 is along a direction perpendicular to the row direction (i.e. a column direction), and the length direction of a third part of second mark units 211c3 is at an angle of 45° to the row direction.

The first part of the first mark units 111c1 and the second part of the second mark units 211c2 are arranged correspondingly. The second part of the first mark units 111c2 and the third part of the second mark units 211c3 are arranged correspondingly. The third part of the third mark units 111c3 and the first part of the third mark units 211c1 are arranged correspondingly.

In the measurement mark, the arrangement manners of the multiple first mark units in each measurement pair are set to be different, or the arrangement manners of the multiple second mark units in each measurement pair are set to be different. Alternatively, the arrangement manners of the multiple first mark units and the arrangement manners of the multiple second mark units in each measurement pair are both set to be different. In this way, the asymmetry of the intensity distribution of the zero-order diffracted light can be enhanced, so as to better accurately measure the overlay error.

An exemplary embodiment provides a measurement mark. In the measurement mark, the number of first mark units is different from the number of the second mark units. That is, in each measurement pair, the number of the multiple first mark units is different from the number of the multiple second mark units, so as to enhance the asymmetry of the intensity distribution of the zero-order diffracted light.

In each measurement pair, the number of the first mark units is denoted as a first number, and the number of the second mark units is denoted as a second number. The first number is greater than the second number, or the second number is greater than the first number.

### Example 1

Referring to FIG. 9, first mark units 111d are first rectangular units, and second mark units 211d are second rectangular units. In each measurement pair, the first number is 4 and the second number is 3.

### Example 2

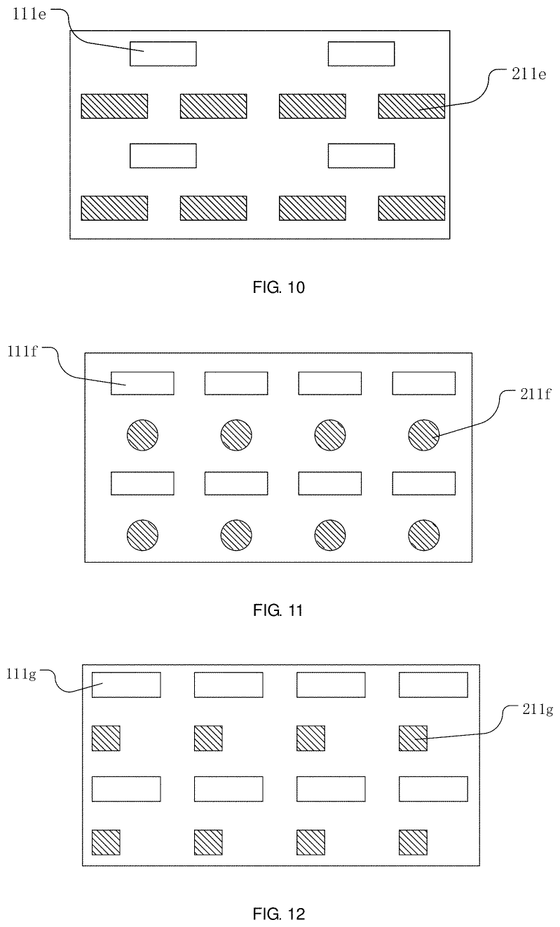

Referring to FIG. 10, first mark units 111e are first rectangular units, and second mark units 211e are second rectangular units. In each measurement pair, the first number is 2 and the second number is 4.

The shapes of the first mark units and the second mark units may also be different, so as to enhance the asymmetry of the intensity distribution of the zero-order diffracted light.

### Example 3

Referring to FIG. 11, first mark units 111f are rectangular units, and second mark units 211f are circular units.

### Example 4

Referring to FIG. 12, first mark units 111g are rectangular units, and second mark units 211g are square units.

The dimensions of the first mark units and the second mark units may also be different, so as to enhance the asymmetry of the intensity distribution of the zero-order diffracted light.

### Example 5

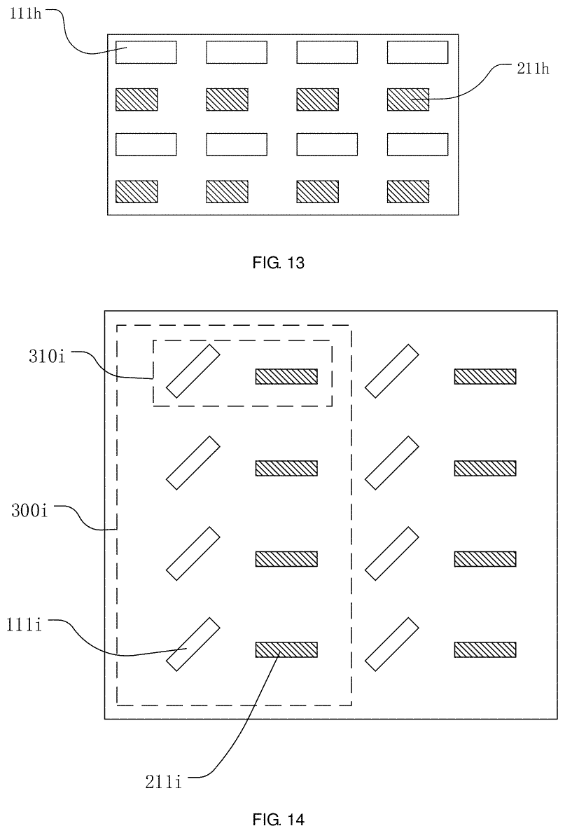

Referring to FIG. 13, first mark units 111h and second mark units 211h are rectangular units, respectively. The length of a long side of each of the first mark units 111h is greater than the length of the long side of each of the second mark units 211h. The length of a broad side of each of the second mark units 211h is equal to the length of the broad side of each of the second mark units 211h.

It should be noted that, except for the dimension and shape, other features of the first and second mark units may also be set to be different at the same time, so as to better enhance the asymmetry of the intensity distribution of the zero-order diffracted light and further improve the accuracy of the overlay error measurement. In addition, since there are multiple arrangement manners in the measurement mark, the applicable scenarios of the measurement mark are expanded. Therefore, it is convenient to set the measurement mark in different manners on different layers, so as to better realize the measurement of the overlay error between different layers.

An exemplary embodiment provides a measurement mark. In the measurement mark, in the projections of the measurement pair on the substrate, projections of multiple first mark units and projections of multiple second mark units are staggered or intersect with each other.

The staggering of the projections of the multiple first mark units with the projections of the multiple second mark units means that the projection of any first mark unit is not intersected with the projection of any second mark unit.

### Example 1

Referring to FIG. 14, the measurement mark includes two measurement pairs 300i. Each measurement pair 300i includes one column of first mark units 111i and one column of second mark units 211i. The one column of first mark units 111i includes four first mark units 111i, and the one column of second mark units 211i includes four second mark units 211i. The projections of the one column of first mark units 111i on the substrate and the projections of the one column of second mark units 211i on the substrate are staggered with each other.

The intersection of the projections of the multiple first mark units with the projections of the multiple second mark units refers to the intersection of the projections of at least one first mark unit and at least one second mark unit.

### Example 2

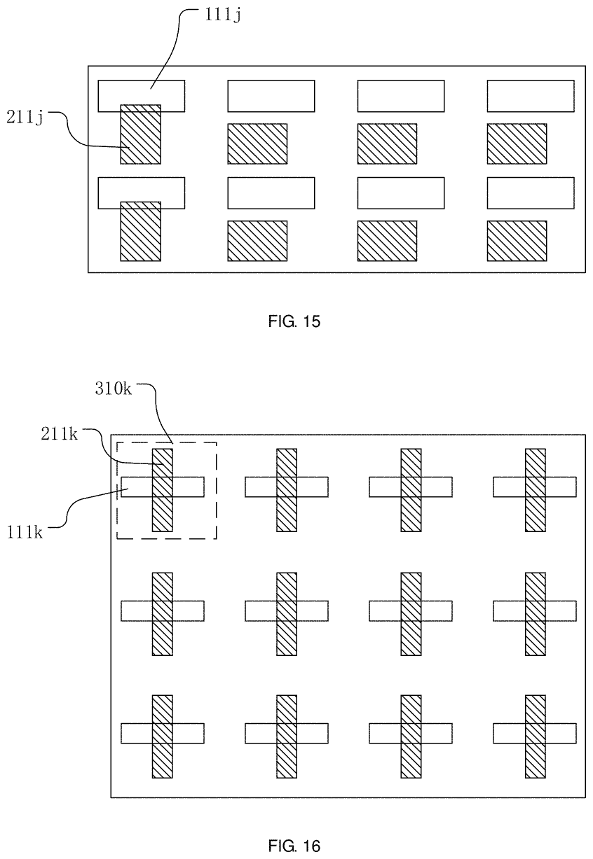

Referring to FIG. 15, the measurement mark includes two measurement pairs. Each measurement pair includes one row of first mark units 111j and one row of second mark units 211j. The one row of first mark units 111j includes four first mark units 111j, and the one row of second mark units 211j includes four second mark units 211j. Only the projection of an initial first mark unit 111j on the substrate is intersected with the projection of an initial second mark unit 211j on the substrate.

### Example 3

Referring to FIG. 16 (the dotted lines in FIG. 16 are only to show a first mark unit 111k and a second mark unit 211k included in a sub-pair 310k), a measurement mark includes three measurement pairs. Each of the measurement pairs includes one row of first mark units 111k and one row of second mark units 211k. The one row of first mark units 111k includes four first mark units 111k, and the one row of second mark units 211k includes four second mark units 211k. In each of the measurement pairs, the projections of the first mark units 111k on the substrate are intersected in pairs with the projections of the second mark units 211k on the substrate.

Each of the measurement pairs may include multiple sub-pairs. Each of the sub-pairs may include one first mark unit and one second mark unit. The projections of the sub-pairs on the substrate are staggered to facilitate the setting of the measurement mark.

In the projections of each of the sub-pairs, a projection of the first mark unit on the substrate and a projection of the second mark unit on the substrate may be staggered or intersect with each other.

Referring to FIG. 14, in the projections of each of the measurement pairs on the substrate, when the projections of the multiple first mark units 111i and the projections of the multiple second mark units 211i are staggered with each other, in the projections of each of the sub-pairs 310i on the substrate, the projection of the first mark unit 111i and the projection of the second mark unit 211i are staggered with each other.

Referring to FIG. 16, in the projections of any of the sub-pairs 310k on the substrate, when the projection of the first mark unit 111k is intersected with the projection of the second mark unit 211k, in the projections of each of the measurement pairs on the substrate, the projections of the multiple first mark units 111k are intersected with the projections of the multiple second mark units 211k.

In the measurement mark, in the projections of each of the measurement pairs on the substrate, the projections of the multiple first mark units and the projections of the multiple second mark units may be staggered or intersect with each other. In the projections of each of the sub-pairs on the substrate, the projection of the first mark unit and the projection of the second mark unit may be staggered or intersect with each other. The above solutions provide more arrangement manners for the measurement mark, which expands the applicable scenarios of the measurement mark and facilitates the measurement of the overlay error between different layers.

An exemplary embodiment provides a semiconductor structure. The semiconductor structure is provided with the above-mentioned measurement mark, so as to realize the measurement of an overlay error between different layers through the above-mentioned measurement mark.

Referring to FIGS. 1 to 3, a measurement mark 2 is located in a scribe lane region 12 of a semiconductor structure 1 to avoid damaging active areas 11 of the semiconductor structure 1. The overlay error between different layers can be measured by the measurement mark 2 located in the scribe lane region 12, and then the overlay error of the pattern of the active areas 11 between different layers can be obtained, thereby improving the yield of the semiconductor structure 1.

Referring to FIGS. 1 to 3, the semiconductor structure 1 may further include a first layer 10 and a second layer 20. The first mark layer 100 of the measurement mark 2 belongs to the first layer 10, and the second mark layer 200 of the measurement mark 2 belongs to the second layer 20. The first layer 10 may be located above the second layer 20.

Referring to FIGS. 1 to 3, during a measurement, measurement light is incident from the first layer 10. After passing through a first mark group 110 of the first layer 10 and a second mark group 210 of the second layer 20, an intensity distribution of zero-order diffracted light of the measurement light is asymmetric. According to the asymmetry, an overlay error of the first layer 10 and the second layer 20 is calculated.

The measurement mark 2 of the semiconductor structure 1 is specially used for overlay error measurement, and the measurement mark 2 is provided in the scribe lane region 12. Therefore, even if the first layer 10 or the second layer 20 is an opening layer or the first layer 10 and the second layer 20 are both opening layers, the measurement of the overlay error between the first layer 10 and the second layer 20 will not be affected.

For example, when the first layer 10 is provided with multiple openings, that is, the first layer 10 is an opening layer, the above-mentioned measurement mark 2 can still accurately measure the overlay error between the pattern of the active areas 11 of the first layer 10 and the pattern of the active areas 11 of the second layer 20.

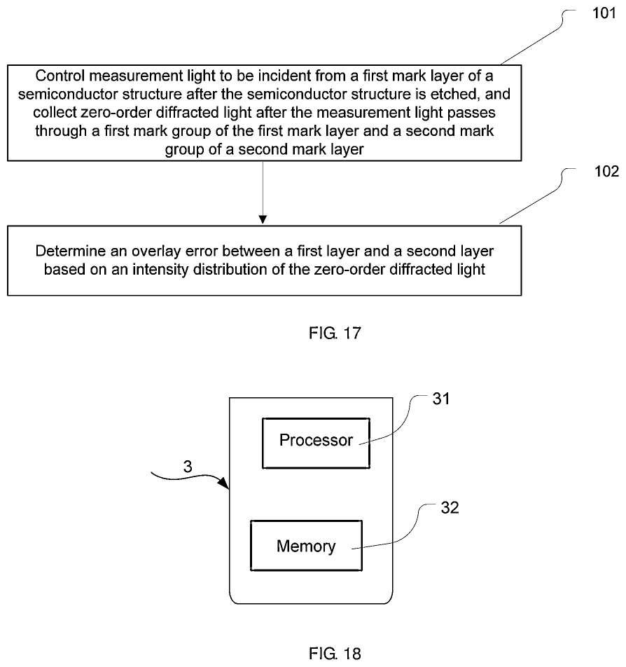

An exemplary embodiment provides a measurement method for an overlay error. Referring to FIG. 17, the measurement method may include:

S101: Control measurement light to be incident from a first mark layer of a semiconductor structure after the semiconductor structure is etched, and collect zero-order diffracted light after the measurement light passes through a first mark group of the first mark layer and a second mark group of a second mark layer.

S102: Determine an overlay error between a first layer and a second layer based on an intensity distribution of the zero-order diffracted light.

The first mark layer and the second mark layer form the above-mentioned measurement mark. That is, the measurement method is applied to the above-mentioned semiconductor structure provided with the measurement mark.

This measurement method is different from general IBO and IDM, but combines the advantages of general IBO and IDM. The measurement method presets the measurement mark in the semiconductor structure, which realizes the measurement of the overlay error based on the intensity distribution of the zero-order diffracted light, and can realize the measurement of the overlay error between any layers of the semiconductor structure. That is, the measurement method can accurately measure the overlay error between an opening layer and other layer, so as to improve the product yield.

The measurement mark may be located in a scribe lane region of the semiconductor structure. That is, the measurement method is applied to the above-mentioned semiconductor structure provided with the measurement mark in a scribe lane region. By setting the measurement mark in the scribe lane region, the mutual influence between the measurement mark and the pattern of the active areas can be avoided, so as to ensure the performance of the semiconductor structure, ensure the accurate setting of the measurement mark, and further improve the accuracy of the measurement. Meanwhile, the applicable scenarios of measurement mark are expanded.

The measurement method realizes the measurement of the overlay error of the pattern of the active areas of the first layer and the pattern of the active areas of the second layer through the measurement mark located in the scribe lane region. The measurement method improves the accuracy of measurement and improves the product yield.

An exemplary embodiment provides a measurement device. The measurement device is configured to implement the above-mentioned measurement method. The measurement device may be provided as a server. As shown in FIG. 18, the measurement device 3 may include a processor 31, and one or more processors 31 may be provided as required. The measurement device 3 may further include a memory 32, which is configured to store an instruction executable by the processor 31, such as an application program. One or more memories 32 may be provided as required. The memory may store one or more application programs. The processor 31 is configured to execute the instruction so as to execute the above-mentioned measurement method.

For example, the processor 31 is configured to:

control measurement light to be incident from a first mark layer of a semiconductor structure after the semiconductor structure is etched, and collect zero-order diffracted light after the measurement light passes through a first mark group of the first mark layer and a second mark group of a second mark layer; and

determine an overlay error between a first layer and a second layer based on an intensity distribution of the zero-order diffracted light.

An exemplary embodiment provides a non-transitory computer-readable storage medium (not shown in the figure). When an instruction in the storage medium is executed by the processor of the above-mentioned measurement device, the measurement device executes the above-mentioned measurement method.

For example, when the instruction in the storage medium is executed by the processor of the above-mentioned measurement device, the measurement device executes the following tasks:

control measurement light to be incident from a first mark layer of a semiconductor structure after the semiconductor structure is etched, and collect zero-order diffracted light after the measurement light passes through a first mark group of the first mark layer and a second mark group of a second mark layer; and

determine an overlay error between a first layer and a second layer based on an intensity distribution of the zero-order diffracted light.

Persons skilled in the art should understand that the embodiments of the present disclosure may be provided as a method, an apparatus (device), or a computer program product. Therefore, the present disclosure may use a form of hardware only embodiments, software only embodiments, or embodiments with a combination of software and hardware. Moreover, the present disclosure may be in a form of a computer program product that is implemented on one or more computer-usable storage media that include computer-usable program code. The computer storage media include volatile and non-volatile, removable and non-removable media implemented in any method or technology for storing information (such as computer-readable instructions, data structures, program modules, or other data), including but not limited to, a random access memory (RAM), a read-only memory (ROM), an electrically erasable programmable read-only memory (EEPROM), a flash memory or other storage technologies, a compact disc read-only memory (CD-ROM), a digital versatile disk (DVD) or other optical disc storage, a magnetic cassette, a magnetic tape, magnetic disk storage or other magnetic storage apparatuses, or any other medium that can be used to store desired information and can be accessed by a computer. In addition, as is well known to persons of ordinary skill in the art, the communication media usually contain computer-readable instructions, data structures, program modules, or other data in modulated data signals such as carrier waves or other transmission mechanisms, and may include any information transfer medium.

The present disclosure is described with reference to the flowcharts and/or block diagrams of the method, the apparatus (device), and the computer program product according to the embodiments of the present disclosure. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of any other programmable data processing device to generate a machine, so that the instructions executed by a computer or a processor of any other programmable data processing device generate an apparatus for implementing a specific function in one or more processes in the flowcharts and/or in one or more blocks in the block diagrams.

These computer program instructions may also be stored in a computer readable memory that can instruct the computer or any other programmable data processing device to work in a specific manner, so that the instructions stored in the computer readable memory generate an artifact that includes an instruction apparatus. The instruction apparatus implements a specific function in one or more processes in the flowcharts and/or in one or more blocks in the block diagrams.

These computer program instructions may also be loaded onto a computer or another programmable data processing device, such that a series of operations and steps are performed on the computer or another programmable device, thereby generating computer-implemented processing. Therefore, the instructions executed on the computer or another programmable device provide steps for implementing a specific function in one or more processes in the flowcharts and/or in one or more blocks in the block diagrams.

In the specification, the terms “include”, “comprise”, or any other variations thereof are intended to cover a non-exclusive inclusion, so that an article or a device including a series of elements not only includes those elements, but also includes other elements that are not explicitly listed, or also includes inherent elements of the article or the device. Without more restrictions, the elements defined by the statement “including a . . . ” do not exclude the existence of other identical elements in the article or device including the elements.

Although some preferred embodiments of the present disclosure have been described, persons skilled in the art can make changes and modifications to these embodiments once they learn the basic inventive concept. Therefore, the appended claims are intended to be interpreted as including the preferred embodiments and all changes and modifications falling within the scope of the present disclosure.

Apparently, persons skilled in the art can make various changes and modifications to the present disclosure without departing from the spirit and scope of the present disclosure. In this way, if these changes and modifications to the present disclosure fall within the scope of the claims of the present disclosure and equivalent technologies thereof, the present disclosure is further intended to include these changes and modifications.

### INDUSTRIAL APPLICABILITY

The present disclosure provides a measurement mark, a semiconductor structure, a measurement method, a device and a storage medium. After measurement light passes through the measurement mark, an intensity distribution of zero-order diffracted light of the measurement light is asymmetric. According to the asymmetry of the intensity distribution of the zero-order diffracted light, an overlay error between a first mark group of a first mark layer (for example, a current layer) and a second mark group of a second mark layer (for example, a previous layer) in the measurement mark can be calculated. In this way, the overlay error between the current layer and the previous layer of the semiconductor structure can be obtained, thereby realizing accurate measurement of the overlay error. The measurement mark can be used to measure the overlay error between any two layers of the semiconductor structure.

1. A measurement mark for an overlay error, the measurement mark being provided on a semiconductor structure, the semiconductor structure comprising a substrate; the measurement mark being applied to an after etching inspection process; the measurement mark comprising a first mark layer and a second mark layer, the first mark layer and the second mark layer being stacked; a projection contour of the first mark layer on the substrate coinciding with a projection contour of the second mark layer on the substrate;
the measurement mark comprising a first mark group located on the first mark layer and a second mark group located on the second mark layer; and
the measurement mark being configured such that after measurement light passes through the first mark group and the second mark group, an intensity distribution of zero-order diffracted light of the measurement light is asymmetric.

2. The measurement mark according to claim 1, wherein the measurement mark comprises at least one measurement pair; the measurement pair comprises multiple first mark units in the first mark group and multiple second mark units in the second mark group; and projections of multiple measurement pairs on the substrate are staggered.

3. The measurement mark according to claim 2, wherein in the measurement pair, the multiple first mark units are arranged in a first preset manner, and the multiple second mark units are arranged in a second preset manner; the first preset manner is a row manner or a column manner, and the second preset manner is the row manner or the column manner.

4. The measurement mark according to claim 2, wherein in the measurement pair,
the multiple first mark units are arranged in different manners; and/or,
the multiple second mark units are arranged in different manners.

5. The measurement mark according to claim 2, wherein a number of the multiple first mark units is different from a number of the multiple second mark units.

6. The measurement mark according to claim 2, wherein the first mark units and the second mark units have different shapes.

7. The measurement mark according to claim 2, wherein the first mark units and the second mark units have different dimensions.

8. The measurement mark according to claim 2, wherein in the projections of the measurement pair on the substrate, projections of the multiple first mark units and projections of the multiple second mark units are staggered or intersect with each other.

9. The measurement mark according to claim 8, wherein the measurement pair comprises multiple sub-pairs; each of the sub-pairs comprises one first mark unit and one second mark unit; and projections of the multiple sub-pairs on the substrate are staggered.

10. The measurement mark according to claim 9, wherein a projection of the first mark unit on the substrate and a projection of the second mark unit on the substrate are staggered or intersect with each other.

11. The measurement mark according to claim 1, wherein the first mark layer is located in an opening layer of the semiconductor structure.

12. A semiconductor structure, wherein the semiconductor structure is provided with a measurement mark for an overlay error, the measurement mark being provided on a semiconductor structure, the semiconductor structure comprising a substrate; the measurement mark being applied to an after etching inspection process; the measurement mark comprising a first mark layer and a second mark layer, the first mark layer and the second mark layer being stacked; a projection contour of the first mark layer on the substrate coinciding with a projection contour of the second mark layer on the substrate;
the measurement mark comprising a first mark group located on the first mark layer and a second mark group located on the second mark layer; and
the measurement mark being configured such that after measurement light passes through the first mark group and the second mark group, an intensity distribution of zero-order diffracted light of the measurement light is asymmetric.

13. The semiconductor structure according to claim 12, wherein the measurement mark is located in a scribe lane region of the semiconductor structure.

14. The semiconductor structure according to claim 13, wherein the semiconductor structure further comprises active areas; and the scribe lane region is located on a periphery of the active areas.

15. The semiconductor structure according to claim 14, wherein the measurement mark is provided in multiple positions in the scribe lane region on the periphery of the active areas.

16. The semiconductor structure according to claim 13, wherein the semiconductor structure comprises a first layer and a second layer; the first mark layer of the measurement mark belongs to the first layer, and the second mark layer of the measurement mark belongs to the second layer; and the first layer is located above the second layer.

17. The semiconductor structure according to claim 16, wherein the first layer is provided with multiple openings.

18. A measurement method for an overlay error, comprising:
controlling measurement light to be incident from a first mark layer of a semiconductor structure after the semiconductor structure is etched, and collecting zero-order diffracted light after the measurement light passes through a first mark group of the first mark layer and a second mark group of a second mark layer of the semiconductor structure, wherein the first mark layer and the second mark layer form a measurement mark for an overlay error, the measurement mark being provided on a semiconductor structure, the semiconductor structure comprising a substrate; the measurement mark being applied to an after etching inspection process; the measurement mark comprising a first mark layer and a second mark layer, the first mark layer and the second mark layer being stacked; a projection contour of the first mark layer on the substrate coinciding with a projection contour of the second mark layer on the substrate;
the measurement mark comprising a first mark group located on the first mark layer and a second mark group located on the second mark layer; and
the measurement mark being configured such that after measurement light passes through the first mark group and the second mark group, an intensity distribution of zero-order diffracted light of the measurement light is asymmetric, and the measurement mark is located in a scribe lane region of the semiconductor structure; and
determining an overlay error between a first layer and a second layer based on an intensity distribution of the zero-order diffracted light.
